(19) United States
(12) Patent Application Publication
(10) Pub. No.: US 2013/0193569 A1
(43) Pub. Date: Aug. 1, 2013

(54) Integrated Circuit Die And Method Of Fabricating

(71) Applicants: Licheng Marshal Han, Frisco, TX (US); Christopher Daniel Manack, Lewisville, TX (US); Michael Andrew Serafin, Richardson, TX (US)

(72) Inventors: Licheng Marshal Han, Frisco, TX (US); Christopher Daniel Manack, Lewisville, TX (US); Michael Andrew Serafin, Richardson, TX (US)

(73) Assignee: TEXAS INSTRUMENTS INCORPORATED, Dallas, TX (US)

(21) Appl. No.: 13/362,871

(22) Filed: Jan. 31, 2012

(51) Int. Cl. H01L 21/768; H01L 23/485

(52) U.S. Cl. 257/737; 438/687; 438/597; 438/686; 438/652; 257/E23.021; 257/E21.59

(57) ABSTRACT

Integrated circuit dies and methods of fabricating the dies are disclosed. An embodiment of a method includes providing a die having a redistribution layer fabricated thereon. The redistribution layer has a surface located thereon that is free of any seed layers. An under bump metal layer is fabricated directly to the surface.

### BACKGROUND

Some integrated circuits include dies that are fabricated using a wafer level chip scale package (WCSP). The dies are typically associated with flip chip devices and are bonded to a printed circuit board or other substrate by way of a plurality of solder bumps. A solder bump provides electrical and mechanical connections between the printed circuit board and the die. An under bump metallization area is formed on the die in order to electrically and mechanically connect the solder hump to the die.

The under bump metallization may have several metal layers. For example, a diffusion barrier layer and a first seed layer may be deposited onto a wafer. A redistribution layer is then plated onto the seed layer. A portion of the redistribution layer may have a large conductive area that accommodates an under bump metal layer and the solder bump. A second seed layer is deposited onto the large conductive area. The under bump metal layer is then plated onto the second seed layer. The under bump metal layer serves as an interface and diffusion barrier between the solder bump and the redistribution layer. The solder bump is then applied to the under bump metal layer. The combination of these layers under the solder bump is referred to as the under bump metallization.

The fabrication of the under bump metallization is expensive and time consuming. For example, it requires a second seed layer between the redistribution layer and the under bump metal layer. It follows that a second etching process is required to remove excess portions of the second seed layer. In addition, the several layers of the under bump metallization cause weak areas on the die that are susceptible to delamination or other reliability failures. For example, when the completed circuit is placed under physical stress, the layers constituting the under bump metallization may delaminate or otherwise fail. Their failure can cause an open or short failure of the die.

### BRIEF DESCRIPTION OF THE DRAWINGS

FIG. 1 is a schematic illustration of a side view of an embodiment of a die.

FIG. 2 is a flow chart illustrating an embodiment for fabricating the die of FIG. 1.

FIG. 3 is a schematic illustration of a side view of an embodiment of a first step in fabricating the die of FIG. 1.

FIG. 4 is a schematic illustration of a side view of an embodiment of a second step in fabricating the die of FIG. 1.

FIG. 5 is a schematic illustration of a side view of an embodiment of a third step in fabricating the die of FIG. 1.

FIG. 6 is a schematic illustration of a side view of an embodiment of a fourth step in fabricating the die of FIG. 1.

FIG. 7 is a schematic illustration of a side view of an embodiment of a fifth step in fabricating the die of FIG. 1.

FIG. 8 is a schematic illustration of a side view of an embodiment of a sixth step in fabricating the die of FIG. 1.

FIG. 9 is a schematic illustration of a side view of an embodiment of a seventh step in fabricating the die of FIG. 1.

FIG. 10 is a schematic illustration of a side view of an embodiment of a eighth step in fabricating the die of FIG. 1, which is the completed die.

FIG. 11 is a schematic illustration of a side view of an embodiment of a ninth step in fabricating the die of FIG. 1.

FIG. 12 is a schematic illustration of a side view of an embodiment of a eighth step in fabricating the die of FIG. 1, which is the completed die.

### DETAILED DESCRIPTION

Integrated circuit dies and methods of fabricating integrated circuit dies are disclosed herein. The embodiments of the dies and methods described herein may apply to wafer level chip scale packages (WCSP) used in flip chip circuits. The dies and methods disclosed herein relate to fabrication of dies that may be bonded or otherwise connected to substrates or printed circuit boards. Solder bumps located on under bump metallization on the dies are used to bond the dies to the substrates. It is noted that the methods disclosed herein are applicable to circuits other than wafer level chip scale packages.

Reference is made to FIG. 1, which is a schematic, side elevation view of an embodiment of a die 100. The die 100 may be bonded to a substrate (not shown), such as a printed circuit board, using flip chip techniques. The die 100 includes a wafer or substrate 102, which may be a conventional semiconductor wafer. The substrate 102 has an upper surface 104 and an opposite lower surface 106. Circuits (not'shown) may be formed on or in the substrate 102 in a conventional manner.

A seed layer 110 is fabricated onto or deposited onto the top surface 104 of the substrate 102. The seed layer 110 may be fabricated with a diffusion layer or act as a diffusion layer. The seed layer 110 may be applied by conventional sputtering or physical vapor deposition (PVD) techniques. The seed layer 110 may contain a diffusion barrier, such as titanium or tungsten. Other conventional elements may be used in the seed layer 110. The seed layer 110 prevents the materials in the substrate 102 from reacting with materials in the redistribution layer 114 and visa versa. The seed layer 110 also provides a layer to which the redistribution layer 114 may adhere.

As described above, the redistribution layer 114 is affixed to or fabricated onto the seed layer 110. The redistribution layer 114 is a conductive layer that serves to electrically connect components on or in the substrate 102 in a similar way that traces on circuit board electrically connect components on the circuit board. The redistribution layer 114 may be made of copper or other conductive metals. In some embodiments the redistribution layer is applied by way of a conventional plating procedure.

A portion of the redistribution layer 114 is part of an under bump metallization 116. The under bump metallization 116 is a portion of the die 100 that serves to connect a solder bump 120 or other conductor to the substrate 102. As described in greater detail below, the under bump metallization 116 may be proximate a large area of the redistribution layer 114, that accommodates the solder bump 120. In the embodiment described herein, the under bump metallization 116 includes an under bump metal layer 118 that is attached directly to the redistribution layer 114. More specifically, the under bump metallization 116 includes the portions of the under bump metal layer 118, the redistribution layer 114, and the seed layer 110 that are located under a solder bump 120.

In some embodiments, the under bump metal layer 118 contains copper, and/or titanium, and/or tungsten. These materials provide adhesion and electrical conductivity between the solder bump 120 and the redistribution layer 114. In conventional dies, a second seed layer is applied between the redistribution layer and the under bump metal layer. The addition of the second seed layer requires additional steps, such as etching and a PVD or other process to apply the second seed layer. These additional fabrication steps increase the costs of the dies and the time required to fabricate the dies. Another problem with the second seed layer is that it constitutes another bond in the under bump metallization, which makes a weak point in the dye. More specifically, the second seed layer between the redistribution layer and the under bump metal layer creates a portion of the die that is likely to fail when the die is subjected to physical stress. For example, the the under bump metal layer may delaminate or otherwise separate from the redistribution layer due to a failure in the second seed layer. This delamination or separation will likely lead to failure of the die. The die 100 described herein bonds the under bump metal layer 118 directly to the redistribution layer 114 without a second seed layer. Accordingly the die 100 costs less to fabricate and is able to withstand more physical stresses than conventional dies.

The solder bump 120 is attached to the under bump metal layer 118 in a conventional manner. As described in greater detail below, the solder bump 120 electrically and mechanically connects the die 100 to a printed circuit board or a substrate (not shown). The die 100 may then be attached to a printed circuit board by way of the solder bump 120 using conventional techniques.

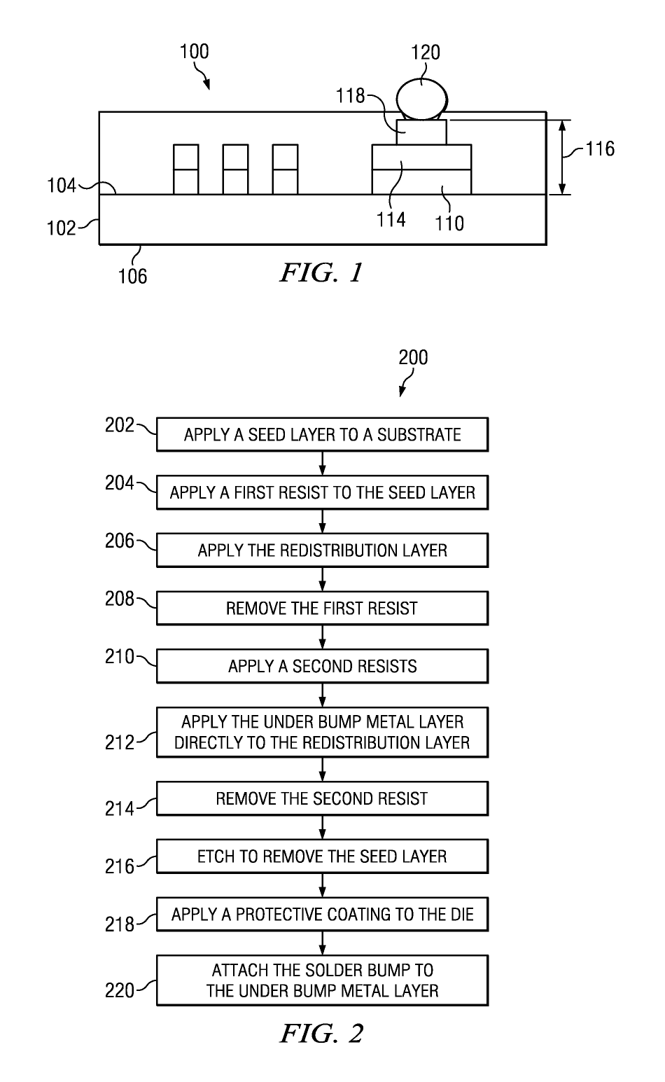

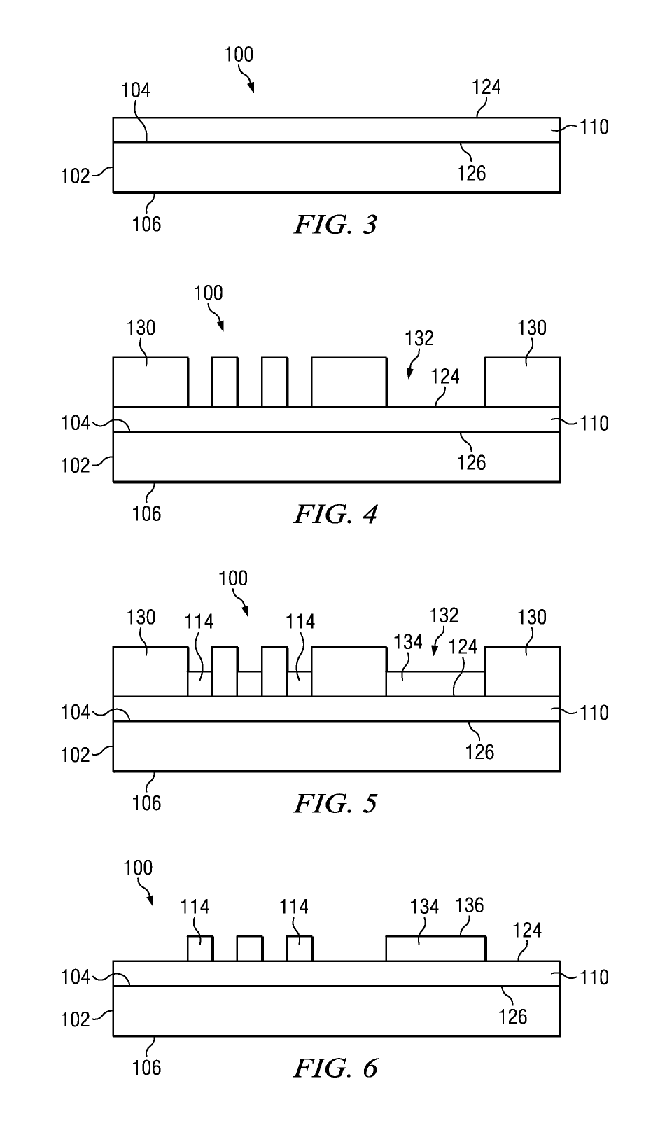

Having described the structure of the die 100, methods of fabricating the die 100 will now be described. Additional reference is made to a flow chart 200 of FIG. 2, which describes some of the fabrication embodiments. Reference is also made to FIG. 3, which is a side elevation view of the partially completed die 100. FIG. 3 shows the substrate 102 with the seed layer 110 formed thereon. Accordingly, the process commences with applying the seed layer 110 to the surface 104 of the substrate 102 and as described by step 202 of the flow chart 200. The seed layer 110 may be applied by conventional techniques, such as by physical vapor deposition. The seed layer 110 may contain copper and/or other elements, such as titanium and/or tungsten, that are commonly used in seed layer fabrication. For reference purposes, the seed layer 110 has a top surface 124 and a bottom surface 126 wherein the bottoms surface 126 is fabricated onto the top surface 104 of the substrate 102.

Fabrication of the die 100 continues by applying a first resist 130 to the substrate 102 as described in step 204 of the flow chart 200 and as shown in FIG. 4. More specifically, the first resist 130 is applied to the top surface 124 of the seed layer 110 a pattern that corresponds to the pattern of the redistribution layer 114, FIG. 1. The first resist 130 prevents the redistribution layer 114 from being applied to the seed layer 110 in areas where the first resist 130 is located. Thus, the first resist 130 prevents the copper plating, or other material, of the redistribution layer 114 from adhering to portions of the seed layer 110 where the redistribution layer 114 is located.

As shown in FIG. 1, the solder bump 120 is relatively large. It follows that the area for the under bump metallization 116 needs to be relatively large. Accordingly, the first resist 130 has an opening 132 that is sized to accommodate the relatively large size of the under bump metallization 116 and the solder bump 120. More specifically, the opening 132 in the first resist 130 will yield a corresponding large conductive portion of the redistribution layer 114 as described below.

After the first resist 130 is applied to the seed layer 110, the redistribution layer 114 is applied to the seed layer 110 as shown in FIG. 5 and described at step 206 of the flow chart 200. The redistribution layer 114 may be applied as a copper plate by way of conventional plating techniques. As described above, the redistribution layer 114 adheres to the seed layer 110, so the redistribution layer 114 will not be present on the die 100 in the locations where the first resist 130 is located. The opening 132 in the first resist 130 yields an under bump portion 134 in the redistribution layer 114 that is substantially as large as the opening 132. The under hump portion 134 serves to hold the under hump metal layer 118 as described below.

After the redistribution layer 114 is applied, the first resist 130 is removed as described in step 208 of the flow chart 200. When the first resist 130 is removed, the die 100 appears as shown in FIG. 6. The die 100 at this point consists of the substrate 102, the seed layer 110, and the redistribution layer 114. The redistribution layer 114 includes the under bump portion 134, which has a surface 136 on which the under bump metal layer 118 will be fabricated. It is noted that no additional seed layer is applied to the surface 136.

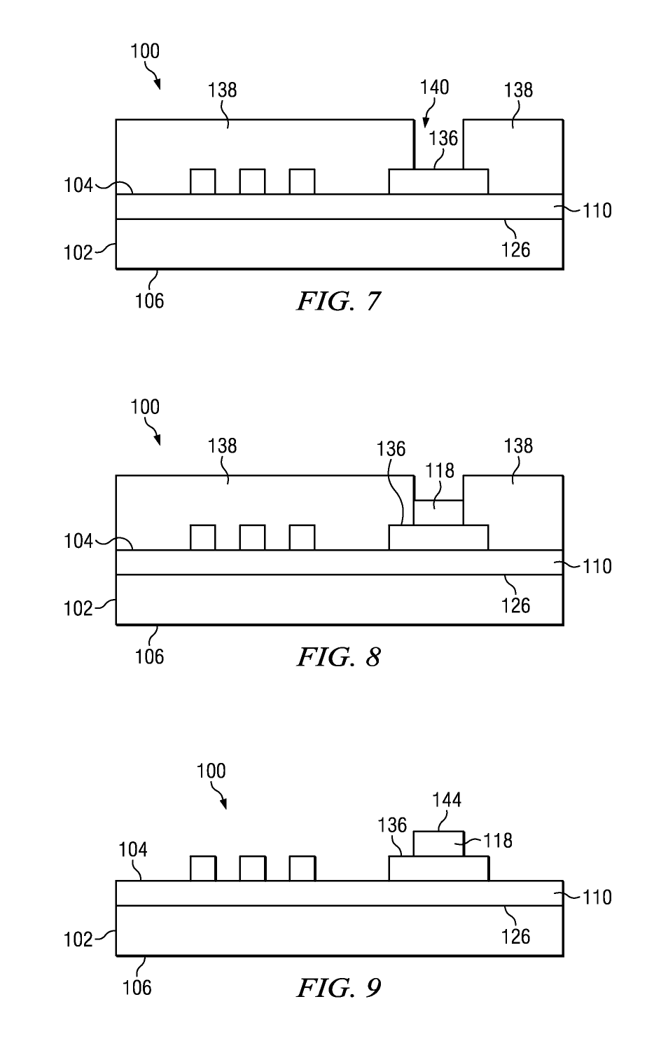

Now that the redistribution layer 114 has been adhered to the die 100, fabrication of the under bump metallization 116 continues with the application of a second resist 138 on the redistribution layer 114 as shown in FIG. 7 and as described in step 210 of the flow chart 200. The second resist 138 covers all portions of the die 100 except for the surface 136 onto which the under bump metal layer 118, FIG. 1, will be fabricated. As shown in FIG. 7, the second resist 138 has an opening 140 that corresponds to the location of the under bump metal layer 118 on the surface 136. It is noted that the second resist 138 may be located partially on the surface 136 so that the under bump metal layer 118 does not cover the entire surface 136. Accordingly, the under bump metal layer 118 may have a surface area that is smaller than the area of the surface 136 of the redistribution layer 114.

At this point, the under bump metal layer 118 is fabricated onto the die 100 as shown in FIG. 8 and as described at step 212 of FIG. 2. More specifically, the under bump metal layer 118 is fabricated directly onto the redistribution layer 114 without the addition of any other seed layers. More specifically, no seed layers are placed between the under bump metal layer 118 and the redistribution layer 114. In one embodiment, the under bump metal layer 118 is fabricated onto the redistribution layer 114 by a conventional plating procedure, such as copper plating. Other materials that may be used for the under bump metal layer 118 include plated nickel/palladium, plated nickel/gold, and plated nickel/copper.

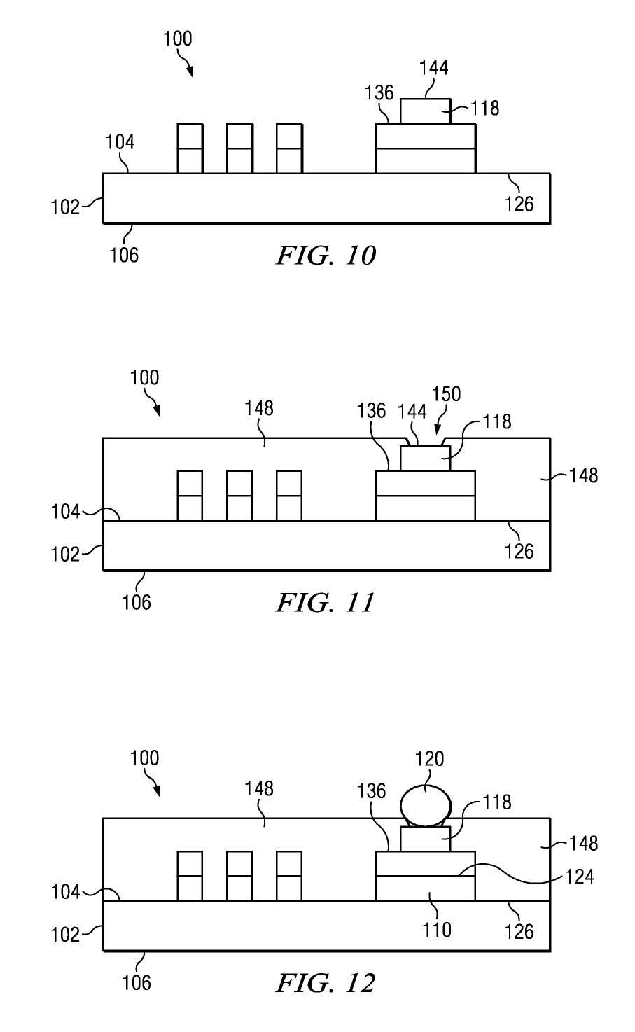

As described in step 214 of the flow chart 200 and shown in FIG. 9, the second resist 138 is now removed. The die 100 now has the addition of the under bump metal layer 118. The under bump metal layer 118 has a surface 144 on which the solder bump 120, FIG. 1, is adhered during a later stage of fabrication. In addition to removing the second resist 138, the die 100 may also be etched to remove remnants of the seed layer 110 as described in step 216 of the flow chart 200. The resulting die 100 is show in FIG. 10. Because the process only has one seed layer applied, only one etching process 216 is required.

A protective coating 148 may be applied to the die as described at step 218 of FIG. 2 and as shown in FIG. 11. The protective coating 148 may be polymide or another conventional coating. The protective coating 148 has an opening 150 proximate the surface 144 on the under bump metal layer 118. The opening 150 serves to keep the protective coating 148 from adhering or otherwise coating the surface 144. Otherwise, the solder bump 120, FIG. 1, would likely not adhere to the surface 144.

The solder bump 120 is attached or fabricated to the surface 144 of the under bump metal layer 118 in a conventional manner as described in step 220 of the flow chart 200. The resulting die 100 is the final product and is shown in FIG. 12.

As stated above, conventional dies use a seed layer between the redistribution layer and the under bump metal layer. For example, titanium and/or tungsten may be sputtered onto the redistribution layer prior to plating the under bump metal layer to the die. This additional seed layer is costly and time consuming. The additional time and costs include removing the remnants of the second seed layer by a second etching process, which is not required with the die 100 described herein. In addition, the second seed layer provides more areas of the die that are subject to failure. The failures include delamination and crack propagation during temperature testing and physical stress testing. other failures may occur between the redistribution layer and the under bump metal layer as a result of the second seed layer.

As stated above, the die 100 described herein has the under bump metal layer 118 plated or otherwise fabricated directly to the redistribution layer 114. The process of fabricating the die 100 described herein is accomplished without the above-described addition of a seed layer between the redistribution layer 114 and the under bump metal layer 118. Accordingly, the bond between the redistribution layer 114 and the under bump metal layer 118 is not as likely to delaminate or separate as with conventional dies. In addition, the cost and time to fabricate the die 100 is reduced relative to conventional dies.

While illustrative and presently preferred embodiments of the invention have been described in detail herein, it is to be understood that the inventive concepts may be otherwise variously embodied and employed and that the appended claims are intended to be construed to include such variations except insofar as limited by the prior art.

1. A method of fabricating an integrated circuit die, said method comprising:
providing a die having a redistribution layer fabricated thereon, said redistribution layer having a surface, said surface being free of any seed layers; and
fabricating an under bump metal layer directly to said surface.

2. The method of claim 1, wherein said surface comprises copper.

3. The method of claim 1, wherein said under bump metal layer comprises copper.

4. The method of claim 1, wherein said under bump metal layer comprises nickel.

5. The method of claim 1, wherein said under bump metal layer comprises palladium.

6. The method of claim 1, wherein said under bump metal layer comprises gold.

7. The method of claim 1, wherein said under bump metal layer comprises copper.

8. A method of fabricating an integrated circuit die, said method comprising:
applying a seed layer to a substrate;
applying a first resist to said seed layer, said first resist including a portion for an under bump metal layer;
adhering a first conductive layer to said seed layer, wherein said first conductive layer does not adhere to said seed layer in locations where said first resist is located;
removing said first resist;
applying a second resist to said first conductive layer, wherein said second resist is not applied to the portion of said first conductive layer proximate said under bump metal layer is to be located; and
applying said under bump metal layer directly to said first conductive layer in the area where said second resist is not located;
wherein no seed layers are located between said first conductive layer and said under metal bump layer.

9. The method of claim 8, wherein said first conductive layer is a redistribution layer.

10. The method of claim 8, wherein said first conductive layer comprises copper.

11. The method of claim 8, wherein said under bump metal layer comprises copper.

12. The method of claim 8, wherein said under bump metal layer comprises nickel.

13. The method of claim 8, wherein said under bump metal layer comprises palladium.

14. The method of claim 8, wherein said under bump metal layer comprises gold.

15. The method of claim 8, wherein said under bump metal layer comprises copper.

16. The method of claim 8 and further comprising conducting seed layer etching.

17. An integrated circuit die comprising:
a redistribution layer having a surface, said surface being free of any seed layers; and
an under bump metal layer attached directly to said surface of said redistribution layer.

18. The integrated circuit die of claim 17 and further comprising a solder bump attached to said under bump metal layer.

19. The integrated circuit die of claim 17, wherein said die comprises a single seed layer.

20. The integrated circuit die of claim 19 and further comprising a substrate, wherein said single seed layer is located between said wafer and said redistribution layer.
